(19) United States
(12) Patent Application Publication
(10) Pub. No.: US 2020/0168755 A1
(43) Pub. Date: May 28, 2020

(54) SOLAR CELL MODULE INCLUDING A PLURALITY OF SOLAR CELLS

(71) Applicant: Panasonic Corporation, Osaka (JP)

(72) Inventors: Hiroshi KANNO, Osaka (JP); Junpei IRIKAWA, Osaka (JP); Naoto IMADA, Osaka (JP)

(21) Appl. No.: 16/688,825

(22) Filed: Nov. 19, 2019

(30) Foreign Application Priority Data
Nov. 22, 2018 (JP) 2018-219605

(51) Int. Cl. H01L 31/056; H01L 31/048; H01L 31/05

(52) U.S. Cl. CPC H01L 31/056; H01L 31/0504; H01L 31/0481

(57) ABSTRACT

A 12th solar cell module includes a light receiving surface and a back surface that face in opposite directions. A first film is attached to the light receiving surface. Wires are sandwiched by the first film and the light receiving surface and connected to the 12th solar cell. A second film is attached to the back surface. Wires are sandwiched by the second film and the back surface and connected to the 12th solar cell. The first film is transparent, and the second film is non-transparent.

### CROSS-REFERENCE TO RELATED APPLICATION

This application is based upon and claims the benefit of priority from the prior Japanese Patent Application No. 2018-219605, filed on Nov. 22, 2018, the entire contents of which are incorporated herein by reference.

### BACKGROUND

### 1. Field

The present disclosure relates to a solar cell module and, more particularly, to a solar cell module including solar cells.

### 2. Description of the Related Art

A film having a plurality of wires attached on one surface thereof is used to make it easy to manufacture a solar cell module. The area around the wire is coated by a solder having a low melting point. The film is layered on the solar cell such that the one surface faces the light receiving surface of the solar cell. Further, another film is layered on the solar cell such that the one surface faces the back surface of the solar cell. By heating the stack formed by the layering to a temperature higher than the melting point of the solder, the wires are connected to the solar cell (see, for example, JP2010-45402).

The solar cell in which a plurality of wires are connected to each of the light receiving surface and the back surface is encapsulated by an encapsulant provided between a protection member on the light receiving surface side (hereinafter, referred to as “first protection member”) and a protection member on the back surface side (hereinafter, referred to as “second protection member”). In order improve the power generation efficiency of the solar cell module having such a structure, it is effective to reflect the light arriving at the back surface side of the solar cell toward the solar cell. For example, the encapsulant provided between the back surface and the second protection member of the solar cell is painted white. To provide a solar cell module painted black, etc., on the other hand, the second protection member in a black color is used. If a white encapsulant is used, however, the white encapsulant will be visible in front of the black second protection member so that the solar cell module is not colored black.

### SUMMARY

The disclosure addresses the above-described issue, and a general purpose thereof is to provide a technology of coloring a solar cell module in a non-white color, while also inhibiting the power generation efficiency from being lowered.

A solar cell module according to one aspect of the present disclosure includes: a solar cell including a first surface and a second surface that face in opposite directions; a first protection member provided on a side of the first surface of the solar cell; a second protection member provided on a side of the second surface of the solar cell; an encapsulant provided between the first protection member and the second protection member to encapsulate the solar cell; a first film attached to the first surface of the solar cell; a plurality of first wiring members sandwiched by the first film and the first surface and connected to the solar cell; a second film attached to the second surface of the solar cell; and a plurality of second wiring members sandwiched by the second film and the second surface and connected to the solar cell. The first film is transparent, and the second film is non-transparent.

### BRIEF DESCRIPTION OF THE DRAWINGS

The figures depict one or more implementations in accordance with the present teaching, by way of example only, not by way of limitations. In the figures, like reference numerals refer to the same or similar elements.

Embodiments will now be described by way of examples only, with reference to the accompanying drawings which are meant to be exemplary, not limiting and wherein like elements are numbered alike in several Figures in which:

FIG. 1 is a plan view showing a structure of a solar cell module according to the embodiment;

FIG. 2 is a cross-sectional view showing a structure of the solar cell module of FIG. 1;

FIG. 3 is a perspective view showing a structure of a wire film used in the solar cell module of FIG. 2;

FIGS. 4A and 4B are cross-sectional views showing a structure of the first film and the second film exhibited before they are attached to the solar cell module of FIG. 2;

FIGS. 5A and 5B are partial cross-sectional views showing a structure of the solar cell module of FIG. 2;

FIGS. 6A and 6B are plan views showing a structure of the solar cell of FIG. 1; and

FIG. 7 is a plan view showing another structure of the solar cell of FIG. 1.

### DETAILED DESCRIPTION

The invention will now be described by reference to the preferred embodiments. This does not intend to limit the scope of the present invention, but to exemplify the invention.

A brief summary will be given before describing the present disclosure in specific details. An embodiment of the present disclosure relates to a solar cell module in which a plurality of solar cells are arranged in a matrix. An encapsulant is provided between the first protection member and the second protection member in the solar cell module. The encapsulant encapsulates a plurality of solar cell. In this process, two adjacent solar cells are connected by a wire film. A wire film is configured as two films connected by a plurality of wires, and the respective films are adhesively attached to adjacent solar cells, thereby connecting the filter electrodes of the respective solar cells by the plurality of wires. Since the wire plays the role of a wiring member, a string is formed by a plurality of solar cells arranged in a direction of extension of the wire. A wire film like this is used to make it easy to manufacture a solar cell module.

One of these two films (hereinafter, referred to as “first film”) is attached to the light receiving surface of one solar cell, and the other of the two films (hereinafter, referred to as “second film”) is attached to the back surface of the adjacent solar cell. Thus, by using a wire film in a solar cell module in which the first protection member, the encapsulant, and the second protection member are arranged in the direction away from the light receiving surface side toward the back surface side, the first film, the solar cell, and the second film are arranged in the encapsulant in that direction. As mentioned above, it is effective, in order to improve the power generation efficiency of the solar cell module, to reflect the light incident from the first protection member side and arriving at the back surface side of the solar cell toward the solar cell. Such reflection is realized by, for example, coloring the encapsulant provided between the back surface of the solar cell and the second protection member white, or coloring the second protection member white.

Meanwhile, there are cases where a solar cell module colored in a non-white color such as black is provided to improve the aesthetic appearance of the solar cell module. In this process, the black second protection member is used. If a white encapsulant is used to improve the power generation efficiency, however, the white encapsulant will be visible in front of the black second black protection member from the light receiving surface side. It would therefore be difficult to provide a solar cell module colored black. In order to color the solar cell module in a non-white color, while also inhibiting the power generation efficiency from being lowered, the black second protection member and a transparent encapsulant are used, and a transparent first film and a white second film are also used in the solar cell module according to the embodiment. The terms “parallel” and “perpendicular” in the following description not only encompass completely parallel or perpendicular but also encompass off-parallel and off-perpendicular within the margin of error. The term “substantially” means identical within certain limits.

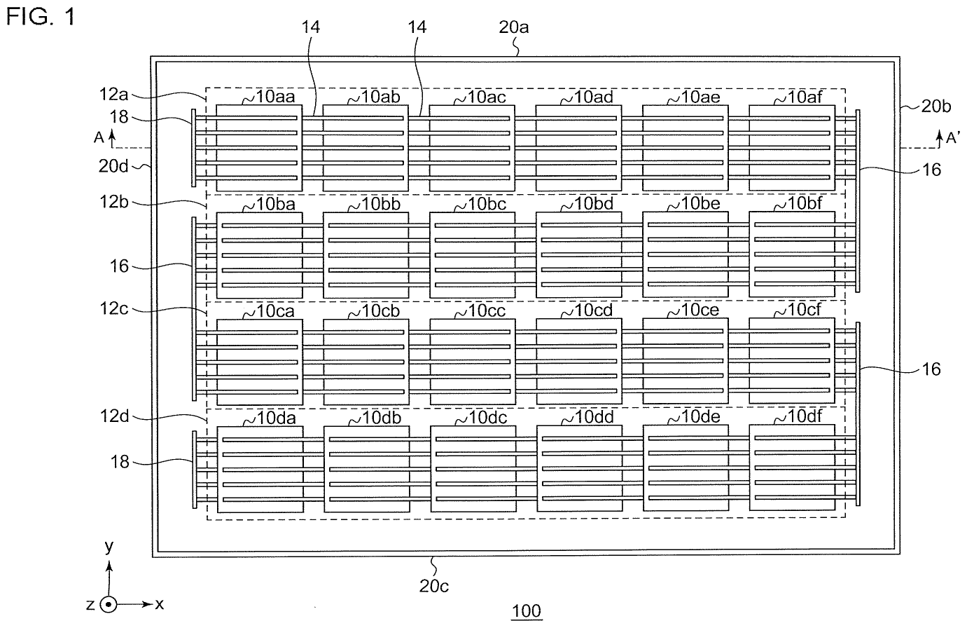

FIG. 1 is a plan view showing a structure of a solar cell module 100. As shown in FIG. 1, an orthogonal coordinate system including an x axis, y axis, and a z axis is defined. The x axis and y axis are orthogonal to each other in the plane of the solar cell module 100. The z axis is perpendicular to the x axis and y axis and extends in the direction of thickness of the solar cell module 100. The positive directions of the x axis, y axis, and z axis are defined in the directions of arrows in FIG. 1, and the negative directions are defined in the directions opposite to those of the arrows. Of the two principal surfaces forming the solar cell module 100 that are parallel to the x-y plane, the principal surface disposed on the positive direction side along the z axis is the light receiving surface, and the principal surface disposed on the negative direction side along the z axis is the back surface. Hereinafter, the positive direction side along the z axis will be referred to as “light receiving surface side” and the negative direction side along the z axis will be referred to as “back surface side”. When the y axis direction is referred to as the “first direction”, the x axis direction is referred to as the “second direction”. Therefore, FIG. 1 can be said to be a plan view of the solar cell module 100 as viewed from the light receiving surface side.

The solar cell module 100 includes an 11th solar cell 10aa, . . . , a 46th solar cell 10df, which are generically referred to as solar cells 10, wires 14, bridge wiring members 16, terminal wiring members 18, a first frame 20a, a second frame 20b, a third frame 20c, and a fourth frame 20d, which are generically referred to as frames 20.

The first frame 20a extends in the x axis direction, and the second frame 20b extends in the negative direction along the y axis from the positive direction end of the first frame 20a along the x axis. Further, the third frame 20c extends in the negative direction along the x axis from the negative direction end of the second frame 20b along the y axis, and the fourth frame 20d connects the negative direction end of the third frame 20c along the x axis and the negative direction end of the first frame 20a along the x axis. The frames 20 bound the outer circumference of the solar cell module 100 and are made of a metal such as aluminum. The first frame 20a and the third frame 20c are longer than the second frame 20b and the fourth frame 20d, respectively, so that the solar cell module 100 has a rectangular shape longer in the x axis direction than in the y axis direction. The shape of the solar cell module 100 is not limited to the illustrated shape.

Each of the plurality of solar cells 10 absorbs incident light and generates photovoltaic power. In particular, the solar cell 10 generates an electromotive force from the light absorbed on the light receiving surface and also generates photovoltaic power from the light absorbed on the back surface. The solar cell 10 is formed by, for example, a semiconductor material such as crystalline silicon, gallium arsenide (GaAs), or indium phosphorus (InP). The structure of the solar cell 10 is not limited to any particular type. It is assumed here that crystalline silicon and amorphous silicon are stacked by way of example. The solar cell 10 is formed in a rectangular shape on the x-y plane but may have other shapes. For example, the solar cell 10 may have an octagonal shape. A plurality of finger electrodes (not shown in FIG. 1) extending in the y axis direction in a mutually parallel manner are disposed on the light receiving surface and the back surface of each solar cell 10. The finger electrode is a collecting electrode.

The plurality of solar cells 10 are arranged in a matrix on the x-y plane. In this case, six solar cells 10 are arranged in the x axis direction. The 6 solar cells 10 arranged and disposed in the x axis direction are connected in series by the wires 14 so as to form one string 12. For example, a first string 12a is formed by connecting the 11th solar cell 10aa, the 12th solar cell 10ab, . . . , and the 16th solar cell 10af. The second string 12b through the fourth string 12d are similarly formed. As a result, the four strings 12 are arranged in parallel in the y axis direction. In this case, the number of solar cells 10 arranged in the x axis direction is larger than the number of solar cells 10 arranged in the y axis direction. The number of solar cells 10 included in the string 12 is not limited to “6”, and the number of strings 12 is not limited to “4”.

In order to form the string 12, the wires 14 connect the finger electrodes on the light receiving surface side of one of the solar cells 10 adjacent to each other in the x axis direction to the finger electrodes on the back surface side of the other. For example, the five wires 14 for connecting the 11th solar cell 10aa and the 12th solar cell 10ab adjacent to each other electrically connect the finger electrodes on the back surface side of the 11th solar cell 10aa and the finger electrodes on the light receiving surface side of the 12th solar cell 10ab. The number of wires 14 is not limited to “5”. Connection between the wires 14 and the solar cell 10 will be described below.

The bridge wiring member 16 extends in the y axis direction and electrically connect the two adjacent strings 12. For example, the 16th solar cell 10af located at the positive direction end of the first string 12a along the x axis and the 26th solar cell 10bf located at the positive direction end of the second string 12b along the x axis are electrically connected by the bridge wiring member 16. Further, the second string 12b and the third string 12c are electrically connected by the bridge wiring member 16 at the negative direction end along the x axis, and the third string 12c and the fourth string 12d are electrically connected by the bridge wiring member 16 at the positive direction end along the x axis. As a result, the plurality of strings 12 are connected in series by the bridge wiring member 16.

The bridge wiring member 16 is not connected to the 11th solar cell 10aa at the negative direction end of the first string 12a along the x axis. Instead the terminal wiring member 18 is connected. The terminal wiring member 18 is also connected to the 41st solar cell 10da at the negative direction end of the fourth string 12d along the x axis. A lead wiring member (not shown) is connected to the terminal wiring member 18. The lead wiring member is a wiring member for retrieving the electric power generated in the plurality of solar cells 10 outside the solar cell module 100.

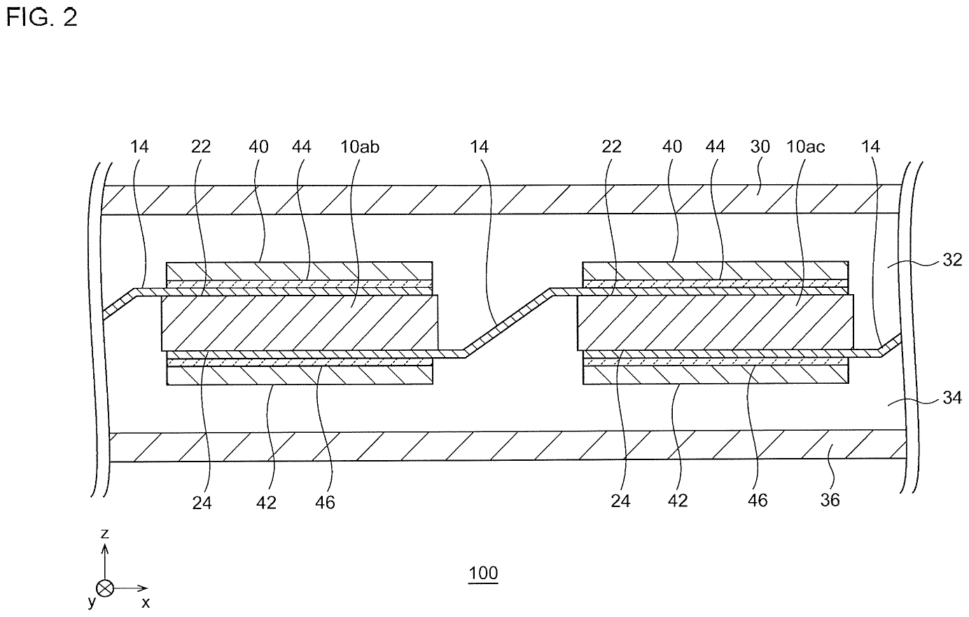

FIG. 2 is a cross-sectional view along the x axis showing a structure of the solar cell module 100 and is an A-A cross-sectional view of FIG. 1. The solar cell module 100 includes a 12th solar cell 10ab, a 13th solar cell 10ac, the wires 14, a first protection member 30, a first encapsulant 32, a second encapsulant 34, a second protection member 36, a first film 40, a second film 42, a first adhesive agent 44, and a second adhesive agent 46. The top of FIG. 2 corresponds to the light receiving surface side, and the bottom corresponds to the back surface side.

The first protection member 30 is disposed on the light receiving surface side of the solar cell module 100 and protects the surface of the solar cell module 100. Further, the solar cell module 100 is shaped in a rectangle bounded by the frames 20 on the x-y plane. The first protection member 30 is formed by using a translucent and water shielding glass, translucent plastic, etc. The first protection member 30 increases the mechanical strength of the solar cell module 100.

The first encapsulant 32 is stacked on the back surface side of the first protection member 30. The first encapsulant 32 is disposed between the first protection member 30 and the solar cell 10 and adhesively bonds the first protection member 30 and the solar cell 10. For example, a thermoplastic resin film of polyolefin, ethylene-vinyl acetate copolymer (EVA), polyvinyl butyral (PVB), polyimide, or the like may be used as the first encapsulant 32. A thermosetting resin may alternatively be used. The first encapsulant 32 is formed by a translucent sheet member having a surface of substantially the same dimension as the x-y plane in the first protection member 30.

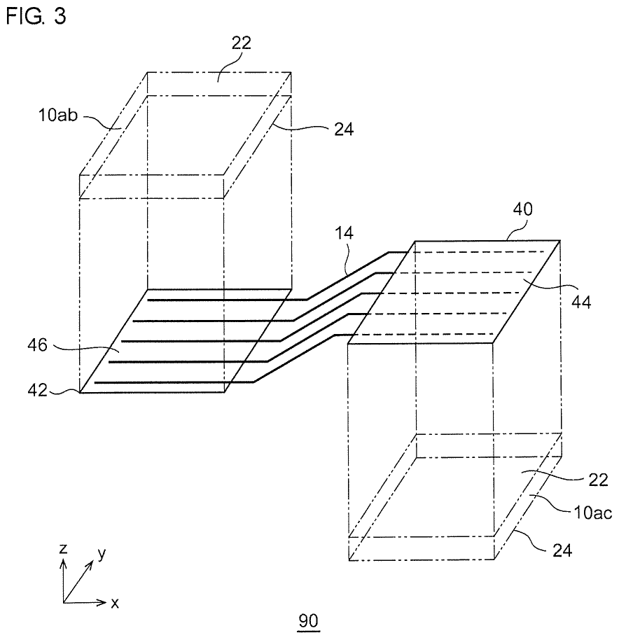

The 12th solar cell 10ab and the 13th solar cell 10ac are stacked on the back surface side of the first protection member 30. The solar cells 10 are provided such that the light receiving surface 22 faces the positive direction side along the z axis and the back surface 24 faces the negative direction side along the z axis. When the light receiving surface 22 is referred to as the “first surface”, the back surface 24 is referred to as the “second surface”. The wires 14, the first adhesive agent 44, and the first film 40 are provided on the light receiving surface 22 of the solar cell 10, and the wires 14, the second adhesive agent 46, and the second film 42 are provided on the back surface 24 of the solar cell 10. FIG. 3 will be used to describe the arrangement of the wires 14, the first film 40, and the second film 42 in the solar cell 10.

FIG. 3 is a perspective view showing a structure of a wire film 90 used in the solar cell module 100. The wire film 90 includes the wires 14, the first film 40, the second film 42, the first adhesive agent 44, and the second adhesive agent 46. The first film 40 is provided on the side of the light receiving surface 22 of one of the two adjacent solar cells 10 (for example, the 13th solar cell 10ac). The first adhesive agent 44 is provided on the surface of the first film 40 toward the 13th solar cell 10ac, and a plurality of wires 14 are provided on the first adhesive agent 44. The first adhesive agent 44 can adhesively bond the light receiving surface 22 of the 13th solar cell 10ac to the first film 40.

The second film 42 is provided on the side of the back surface 24 of the other of the two adjacent solar cells 10 (for example, the 12th solar cell 10ab). The second adhesive agent 46 is provided on the surface of the second film 42 toward the 12th solar cell 10ab, and a plurality of wires 14 are provided on the second adhesive agent 46. The second adhesive agent 46 can adhesively bond the back surface 24 of the 12th solar cell 10ab to the second film 42.

The wire film 90 configured as described above and the solar cell module 100 are manufactured separately. When the solar cell module 100 is manufactured, the first adhesive agent 44 is adhesively bonded to the light receiving surface 22 of the 13th solar cell 10ac, and the second adhesive agent 46 is adhesively bonded to the back surface 24 of the 12th solar cell 10ab. By adhesive bonding as described above, the wires 14 electrically connect the finger electrodes (not shown) on the light receiving surface 22 of the 13th solar cell 10ac to the finger electrodes (not shown) on the back surface 24 of the 12th solar cell 10ab.

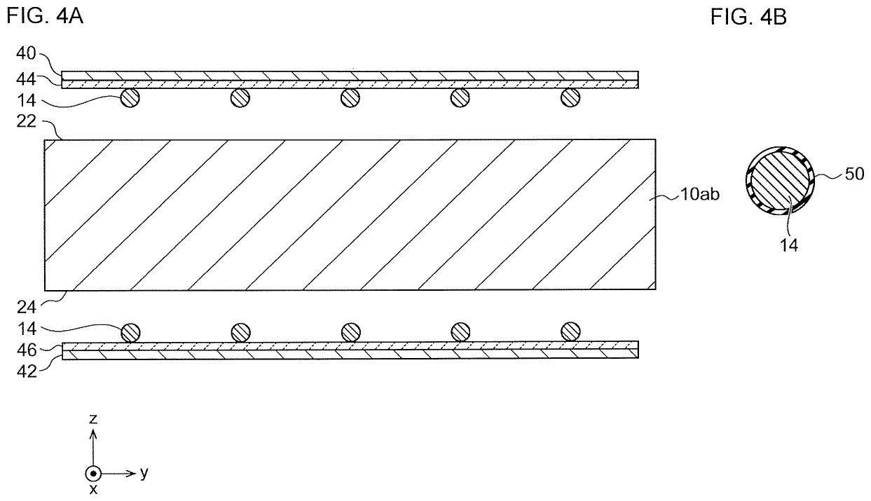

The structure of the first film 40 and the second film 42 shown in FIG. 3 will be described in further detail. FIGS. 4A-4B are cross-sectional views showing a structure of the first film 40 and the second film 42 exhibited before they are attached to the solar cell module 100. In particular, FIG. 4A is a cross-sectional view exhibited when the neighborhood of the 12th solar cell 10ab of FIG. 2 is severed along the y axis and is a cross-sectional view exhibited before the first film 40 and the second film 42 are attached to the 12th solar cell 10ab. As shown in FIG. 2, the first film 40 and the second film 42 shown in FIG. 4A included in mutually different wire films 90.

The first film 40 is formed by a transparent resin film of, for example, polyethylene terephthalate (PET). The first film 40 has rectangular shape of a size equal to or smaller than the size of the solar cell 10 on the x-y plane. For example, polyolefin is used for the first adhesive agent 44 provided on the back surface side of the first film 40, but EVA may be used. The first adhesive agent 44 has a shape similar to that of the first film 40 on the x-y plane. A plurality of wires 14 are provided on the back surface side of the first adhesive agent 44.

FIG. 4B is a cross-sectional view of the wire 14 in the same direction as that of FIG. 4A. The wire 14 extends in a cylindrical shape and has a circular cross section. The wire 14 has a diameter of 100-500 μm, and, preferably, 300 μm, and so is thinner in width of 1-2 mm of a tab line commonly used in a solar cell module. The outer circumference of the wire 14 is coated with a solder layer 50 having a thickness of 5 μm to 30 μm. The solder layer 50 is formed by a solder having a low melting point. For example, the solder has a composition tin-silver-bismuth. In that case, the melting point of the solder layer 50 would be about 140° C. Reference is made back to FIG. 4A. The figure shows five wires 14 by way of example, but, generally, the number of wires 14 is 10-20, which is larger than the number of tab lines commonly used in a solar cell module.

The second film 42 is formed by a non-transparent resin film. For example, the second film 42 is a white resin film. The color of the second film 42 is not limited to white and may be a color having a light reflectance of 80% or higher in the infrared range. The second film 42 has rectangular shape smaller than the solar cell 10 on the x-y plane. More specifically, it is preferred that the interval between the outer edge of the second film 42 and the outer edge of the solar cell 10 be 5 mm or smaller, and, preferably, 2 mm or smaller. As in the first adhesive agent 44, polyolefin or EVA is used for the second adhesive agent 46 provided on the light receiving side of the second film 42. The second adhesive agent 46 has a shape similar to that of the second film 42 on the x-y plane. A plurality of wires 14 are provided on the light receiving surface side of the second adhesive agent 46. The structure of the wire 14 is as shown in FIG. 4B. When the wire 14 provided on the back surface side of the first adhesive agent 44 is referred to as the “first wiring member”, the wire 14 provided on the light receiving surface side of the second adhesive agent 46 is referred to as the “second wiring member”. Reference is made back to FIG. 2.

That the second film 42 is non-transparent means that the total light transmittance of the second film 42 is 80% or lower, the coefficient of haze of the second film 42 is 5% or higher, or the reflectance of the second film 42 is 10% or higher. Meanwhile, that the second film 42 is transparent means that the total light transmittance of the second film 42 is 85% or higher.

By bonding the first film 40 and the second film 42 to the other solar cells 10, the string 12 as shown in FIG. 1 is formed. The second encapsulant 34 is stacked on the back surface side of the first encapsulant 32. The second encapsulant 34 encapsulates the plurality of solar cells 10, the wires 14, the bridge wiring members 16, the terminal wiring members 18, the first films 40, the second films 42, etc., sandwiching the cells, the wires, the members, and the films between the first encapsulant 32 and the second encapsulant 34. The same member as used for the first encapsulant 32 may be used for the second encapsulant 34. The second encapsulant 34 is integrated with the first encapsulant 32 by heating the encapsulants in a laminate cure process.

The second protection member 36 is stacked on the back surface side of the second encapsulant 34 so as to face the first protection member 30. The second protection member 36 protects the back surface side of the solar cell module 100 as a back sheet. A resin film of, for example, PET, polytetrafluoroethylene (PTFE), etc., a stack film having a structure in which an Al foil is sandwiched by resin films of, for example, polyolefin, or the like is used as the second protection member 36. To provide the solar cell module 100 colored in a non-white color such as black, the second protection member 36 is colored in a non-white color (e.g., black). The color of the second protection member 36 is not limited to black. In the case the second encapsulant 34 is colored in a non-white color (e.g., black), for example, the second protection member 36 may be non-white or transparent.

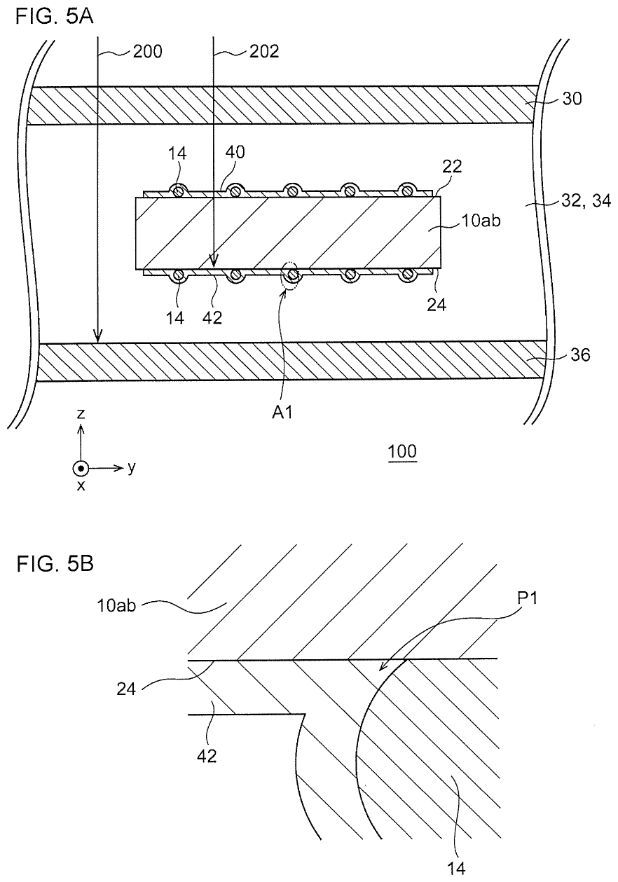

FIG. 5A is a partial cross-sectional view showing a structure of a solar cell module 100 viewed in the same direction as FIG. 4A. The first protection member 30 is provided on the side of the light receiving surface 22 of the 12th solar cell 10ab, and the second protection member 36 is provided on the side of the back surface 24 of the 12th solar cell 10ab. The first encapsulant 32 and the second encapsulant 34 are integrated in a laminate cure process. The integrated encapsulant is provided between the first protection member 30 and the second protection member 36 to encapsulate a plurality of solar cells 10 including the 12th solar cell 10ab. Further, the integrated encapsulant is nearly transparent so that the color of the second protection member 36 is visible when the solar cell module 100 is viewed from the light receiving surface side. Accordingly, the solar cell module colored in a non-white color such as black is provided.

The first film 40 is attached to the light receiving surface 22 of the 12th solar cell 10ab by being bonded by the first adhesive agent 44 of FIG. 4A. The plurality of wires 14 are sandwiched between the first film 40 and the light receiving surface 22, and the plurality of wires 14 are connected to the plurality of finger electrodes (not shown) on the light receiving surface 22 of the 12th solar cell 10ab. The connection is made by melting the solder layer 50 of FIG. 4B. The second film 42 is attached to the back surface 24 of the 12th solar cell 10ab by being bonded by the second adhesive agent 46 of FIG. 4A. The plurality of wires 14 are sandwiched between the second film 42 and the back surface 24, and the plurality of wires 14 are connected to the plurality of finger electrodes (not shown) on the back surface 24 of the 12th solar cell 10ab. The plurality of wires 14 and the plurality of finger electrodes on the light receiving surface 22 of the 12th solar cell 10ab may not be connected by the melting of the solder layer 50, and the solder layer 50 and the finger electrodes may be directly in contact.

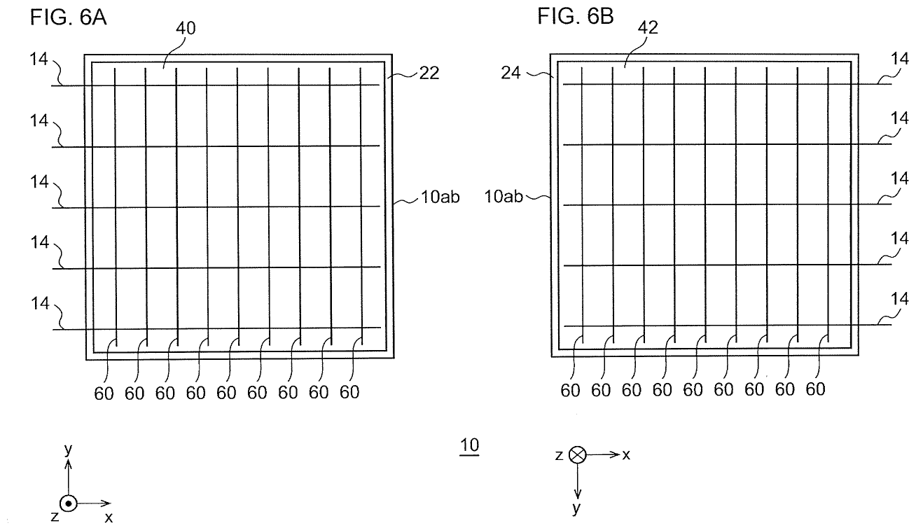

FIGS. 6A-6B are plan views showing a structure of the solar cell 10. FIG. 6A is a plan view showing the 12th solar cell 10ab of FIG. 5A as viewed from the side of the light receiving surface 22. A plurality of finger electrodes 60 extending in the y-axis direction are arranged in the x-axis direction on the light receiving surface 22. The plurality of wires 14 extend on the light receiving surface 22 from the negative direction side along the x axis so as to intersect the plurality of finger electrodes 60. The plurality of wires 14 are sandwiched between the first film 40 and the light receiving surface 22. The first film 40 is configured to be smaller than the light receiving surface 22.

FIG. 6B is a plan view of the 12th solar cell 10ab of FIG. 5A viewed from the side of the back surface 24. A plurality of finger electrodes 60 extending in the y-axis direction are arranged in the x-axis direction on the back surface 24. The number of finger electrodes 60 on the back surface 24 may be larger than the number of finger electrodes 60 on the light receiving surface 22. In that case, the interval between adjacent finger electrodes 60 on the back surface 24 is configured to be smaller than the interval between adjacent finger electrodes 60 on the light receiving surface 22. The plurality of wires 14 extend on the light receiving surface 22 from the positive direction side along the x axis so as to intersect the plurality of finger electrodes 60. The plurality of wires 14 are sandwiched between the second film 42 and the back surface 24. The second film 42 is configured to be smaller than the back surface 24. For this reason, the second film 42 is hidden by the 12th solar cell 10ab when the solar cell module 100 is viewed from the light receiving surface side. This causes the color of the second film 42 not to be visible from the light receiving surface side of the solar cell module 100. Reference is made back to FIG. 5A.

As mentioned above, the first film 40 is transparent so that the light incident from the first protection member 30 arrives at the the light receiving surface 22 of the 12th solar cell 10ab. Further, the second film 42 is white, etc. so that the light incident via the first protection member 30 and transmitted through the 12th solar cell 10ab is reflected by the second film 42 toward the back surface 24 of the 12th solar cell 10ab. FIG. 5B is an enlarged view of the neighborhood of area Al of FIG. 5A. A point P1, a portion of the second film 42 is provided between the back surface 24 of the 12th solar cell 10ab and the wire 14 as well. Such a structure is also seen in each of the plurality of wires 14 provided on the back surface 24 of the 12th solar cell 10ab. As a result, the aforementioned light reflection takes place easily also in the portions of the back surface 24 of the 12th solar cell 10ab where the plurality of wires 14 are provided. Reference is made back to FIG. 5A.

This structure ensures that the reflectance of light 200 incident on the first portion where the solar cell 10 does not exist via the first protection member 30 is 10% or lower in the visible light range. Meanwhile, the reflectance of light 202 incident on the second portion where the solar cell 10 exists via the first protection member 30 is 80% or higher in the infrared range.

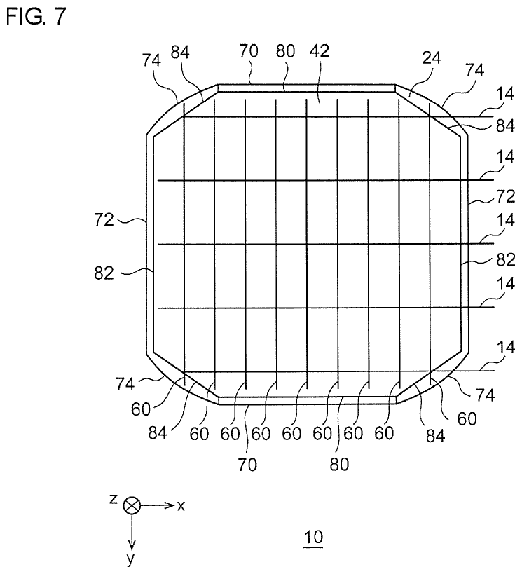

The solar cell 10 is described so far as having a rectangular shape on the x-y plane but may have other shapes. FIG. 7 is a plan view showing another structure of the solar cell 10. This is a plan view of the back surface 24 of the solar cell 10. The solar cell 10 is bounded by two straight first cell edges 70 extending in the x-axis direction, two straight second cell edges 72 extending in the y-axis direction, and curved four third cell edges 74 connecting the first cell edge 70 and the second cell edge 72. The third cell edge 74 is also called a chamfer (C) corner.

The second film 42 is bounded by two first film edges 80, two second film edges 82, and four third film edges 84. The first film edges 80, the second film edges 82, and the third film edges 84 all extend straight. It should be noted that the first film edge 80 extends along the first cell edge 70, the second film edge 82 extends along the second cell edge 72, and the third film edge 84 connect between the first film edge 80 and the second film edge 82. It should also be noted here that the second film 42 is smaller than the back surface 24. The first film 40 (not shown) may have a shape similar to that of the second film 42.

A description will now be given of a method of manufacturing the solar cell module 100. The wire film 90 shown in FIG. 3 is prepared to connect two adjacent solar cells 10. The string 12 is produced by layering the first film 40 of the wire film 90 on one of the two adjacent solar cells 10 and layering the second film 42 of the wire film 90 on the other of the two adjacent solar cells 10. A stack is produced by layering the first protection member 30, the first encapsulant 32, the string 12, the second encapsulant 34, and the second protection member 36 in the stated order in the positive-to-negative direction along the z axis. This is followed by a laminate cure process performed for the stack. In this process, air is drawn from the stack, and the stack is heated and pressurized so as to be integrated. In vacuum lamination in the laminate cure process, the temperature is set to about 50-140°, as mentioned before. Further, a terminal box is attached to the second protection member 36 using an adhesive.

According to the embodiment, the second film 42 attached to the back surface 24 of the solar cell 10 is configured to be non-transparent so that the light arriving at the back surface 24 of the solar cell 10 is reflected toward the solar cell 10. Further, since the light arriving at the back surface 24 of the solar cell 10 is reflected toward the solar cell 10, the power generation efficiency is inhibited from being lowered. Further, since the second film 42 attached to the back surface 24 of the solar cell 10 is configured to be non-transparent, the encapsulant can be transparent even when the power generation efficiency is inhibited from being lowered. Since the encapsulant is configured to be transparent, the color of the second protection member 36 is made visible. Further, since the color of the second protection member 36 is made visible, the solar cell module 100 can be colored in a non-white color. Further, since the solar cell module 100 is colored in a non-white color, the aesthetic appearance of the solar cell module 100 can be improved.

Further, since the second film 42 is a white resin film, the reflectance for the light arriving at the back surface 24 of the solar cell 10 is improved. Further, since the reflectance for the light arriving at the back surface 24 of the solar cell 10 is improved, the power generation efficiency is inhibited from being lowered. More specifically, reflection of light on the second film 42 is fully utilized by configuring the interval between the outer edge of the second film 42 and the outer edge of the solar cell 10 to be 5 mm or smaller. Further, since a portion of the second film 42 may also be provided between the back surface 24 and each of the plurality of wires 14, the reflectance for the light arriving at the back surface 24 of the solar cell 10 is improved.

Further, since the second film 42 is smaller than the back surface 24 of the solar cell 10, the second film 42 is made invisible from the light receiving surface side of the solar cell module 100 even if the second film 42 is non-transparent. Further, since the second film 42 is made invisible from the light receiving surface side of the solar cell module 100, the solar cell module 100 can be colored in a non-white color. Further, since the second film 42 is made invisible from the light receiving surface side of the solar cell module 100, the aesthetic appearance of the solar cell module 100 can be improved.

Further, even when the back surface 24 includes the curved third cell edge 74, the second film 42 is configured to be smaller than the back surface 24 of the solar cell 10 since the second film 42 includes the straight third film edge 84. Further since the second protection member 36 is non-white, the second protection member 36 can be colored. Further, since the light reflectance in the visible light range is 10% or lower in the first portion and the light reflectance in the infrared range is 80% or higher in the second portion, the solar cell module 100 can be colored in a non-white color while also making it possible to inhibit the power generation efficiency from being lowered.

One embodiment of the present disclosure is summarized below. A solar cell module 100 according to one aspect of the present disclosure includes: a solar cell 10 including a light receiving surface 22 and a back surface 24 that face in opposite directions; a first protection member 30 provided on a side of the light receiving surface 22 of the solar cell 10; a second protection member 36 provided on a side of the back surface 24 of the solar cell 10; a first encapsulant 32, a second encapsulant 34 provided between the first protection member 30 and the second protection member 36 to encapsulate the solar cell 10; a first film 40 attached to the light receiving surface 22 of the solar cell 10; a plurality of wires 14 sandwiched by the first film 40 and the light receiving surface 22 and connected to the solar cell 10; a second film 42 attached to the back surface 24 of the solar cell 10; and a plurality of wires 14 sandwiched by the second film 42 and the back surface 24 and connected to the solar cell 10. The first film 40 is transparent, and the second film 42 is non-transparent.

The second film 42 may be a white resin film.

A portion of the second film 42 may also be provided between the back surface 24 of the solar cell 10 and each of the plurality of wires 14.

The second film 42 is smaller than the back surface 24 of the solar cell 10.

The back surface 24 of the solar cell 10 may include straight first and second cell edges 70 and 72 extending in mutually different directions and includes a curved third cell edge 74 connecting the first cell edge 70 and the second cell edge 72. The second film 42 may include a straight first film edge 80 extending along the first cell edge 70, a straight second film edge 82 extending along the second cell edge 72, and a straight third film edge 84 connecting the first film edge 80 and the second film edge 82.

The second protection member 36 may be non-white.

The encapsulant includes a first encapsulant 32 provided on the side of the light receiving surface 22 of the solar cell 10 and a second encapsulant 34 provided on the side of the back surface 24 of the solar cell 10, and the second encapsulant 34 may be non-white.

A reflectance for light incident on a first portion where the solar cell 10 does not exist via the first protection member 30 may be 10% or lower in a visible light range, and a reflectance for light incident on a second portion where the solar cell 10 exists via the first protection member 30 may be 80% or higher in an infrared range.

Described above is an explanation based on an exemplary embodiment. The embodiment is intended to be illustrative only and it will be understood by those skilled in the art that various modifications to constituting elements and processes could be developed and that such modifications are also within the scope of the present disclosure.

What is claimed is:

1. A solar cell module comprising:
a solar cell including a first surface and a second surface that face in opposite directions;
a first protection member provided on a side of the first surface of the solar cell;
a second protection member provided on a side of the second surface of the solar cell;
an encapsulant provided between the first protection member and the second protection member to encapsulate the solar cell;
a first film attached to the first surface of the solar cell;
a plurality of first wiring members sandwiched by the first film and the first surface and connected to the solar cell;
a second film attached to the second surface of the solar cell; and
a plurality of second wiring members sandwiched by the second film and the second surface and connected to the solar cell, wherein
the first film is transparent, and the second film is non-transparent.

2. The solar cell module according to claim 1, wherein
the second film is a white resin film.

3. The solar cell module according to claim 1, wherein
a portion of the second film is also provided between the second surface of the solar cell and each of the plurality of second wiring members.

4. The solar cell module according to claim 2, wherein
a portion of the second film is also provided between the second surface of the solar cell and each of the plurality of second wiring members.

5. The solar cell module according to claim 1, wherein
the second film is smaller than the second surface of the solar cell.

6. The solar cell module according to claim 2, wherein
the second film is smaller than the second surface of the solar cell.

7. The solar cell module according to claim 3, wherein
the second film is smaller than the second surface of the solar cell.

8. The solar cell module according to claim 4, wherein
the second film is smaller than the second surface of the solar cell.

9. The solar cell module according to claim 5, wherein
the second surface of the solar cell includes straight first and second cell edges extending in mutually different directions and includes a curved third cell edge connecting the first cell edge and the second cell edge, and
the second film includes a straight first film edge extending along the first cell edge, a straight second film edge extending along the second cell edge, and a straight third film edge connecting the first film edge and the second film edge.

10. The solar cell module according to claim 6, wherein
the second surface of the solar cell includes straight first and second cell edges extending in mutually different directions and includes a curved third cell edge connecting the first cell edge and the second cell edge, and
the second film includes a straight first film edge extending along the first cell edge, a straight second film edge extending along the second cell edge, and a straight third film edge connecting the first film edge and the second film edge.

11. The solar cell module according to claim 7, wherein
the second surface of the solar cell includes straight first and second cell edges extending in mutually different directions and includes a curved third cell edge connecting the first cell edge and the second cell edge, and
the second film includes a straight first film edge extending along the first cell edge, a straight second film edge extending along the second cell edge, and a straight third film edge connecting the first film edge and the second film edge.

12. The solar cell module according to claim 8, wherein
the second surface of the solar cell includes straight first and second cell edges extending in mutually different directions and includes a curved third cell edge connecting the first cell edge and the second cell edge, and
the second film includes a straight first film edge extending along the first cell edge, a straight second film edge extending along the second cell edge, and a straight third film edge connecting the first film edge and the second film edge.

13. The solar cell module according to claim 1, wherein
the second protection member is non-white.

14. The solar cell module according to claim 1, wherein
the encapsulant includes a first encapsulant provided on the side of the first surface of the solar cell and a second encapsulant provided on the side of the second surface of the solar cell, and
the second encapsulant is non-white.

15. The solar cell module according to claim 1, wherein
a reflectance for light incident on a first portion where the solar cell does not exist via the first protection member is 10% or lower in a visible light range, and a reflectance for light incident on a second portion where the solar cell exists via the first protection member is 80% or higher in an infrared range.
